(19) United States
(12) Patent Application Publication
(10) Pub. No.: US 2025/0212671 A1
(43) Pub. Date: Jun. 26, 2025

(54) DISPLAY MODULE AND DISPLAY APPARATUS

(71) Applicant: Hefei Visionox Technology Co., Ltd., Hefei (CN)

(72) Inventors: Yao LI, Hefei (CN); Chao ZHU, Hefei (CN); Wenzhi FAN, Hefei (CN); Pengji ZHANG, Hefei (CN); Qiteng MA, Hefei (CN)

(73) Assignee: Hefei Visionox Technology Co., Ltd., Hefei (CN)

(21) Appl. No.: 19/075,704

(22) Filed: Mar. 10, 2025

Related U.S. Application Data
(63) Continuation of application No. PCT/CN2024/084763, filed on Mar. 29, 2024.

(30) Foreign Application Priority Data
Jul. 27, 2023 (CN) 202310934889.X

(51) Int. Cl. H10K 59/80; H10K 59/122

(52) U.S. Cl. CPC H10K 59/8792; H10K 59/122

(57) ABSTRACT

The present application discloses a display module and a display apparatus. The display module includes a base plate, a light-emitting layer, and a light-filtering layer. The light-emitting layer is arranged at one side of the base plate and includes a plurality of light-emitting units. The light-filtering layer is arranged at a side of the light-emitting layer away from the base plate and includes a light-filtering portion, a light-shielding portion, and an optical adjustment portion. An orthographic projection of the light-filtering portion on the base plate at least partially overlaps an orthographic projection of the light-emitting unit on the base plate, at least one optical adjustment portion is arranged between adjacent light-filtering portions, the optical adjustment portion at least partially contacts with the light-filtering portion, and a refractive index of the optical adjustment portion is less than a refractive index of the light-filtering portion.

### CROSS REFERENCE TO RELATED APPLICATION

This application is a continuation application of International Application No. PCT/CN2024/084763, filed on Mar. 29, 2024, which claims priority to Chinese patent application No. 202310934889.X, entitled “DISPLAY MODULE, MANUFACTURING METHOD OF DISPLAY MODULE, AND DISPLAY APPARATUS”, filed on Jul. 27, 2023, all of which are hereby incorporated by reference in their entireties.

### TECHNICAL FIELD

The present application relates to the field of display technology, and particularly to a display module and a display apparatus.

### BACKGROUND

Planar display panels such as Liquid Crystal Display (LCD) panels, Organic Light Emitting Diode (OLED) display panels, and display panels using Light Emitting Diode (LED) are widely used in cell phones, TVs, personal digital assistants, digital cameras, notebook computers, desktop computers and other consumer electronic products due to their high image quality, power saving, thin body and wide range of applications, and have become the mainstream of the display apparatus.

At present, how to reduce power consumption of display modules has become an urgent problem to be solved.

### SUMMARY

The purpose of the present application is to provide a display module and a display apparatus, aiming to solve the problem of high power consumption of existing display modules.

In one embodiment of the present application provides a display module, including a base plate, a light-emitting layer, and a light-filtering layer. The light-emitting layer is arranged at one side of the base plate and includes a plurality of light-emitting units. The light-filtering layer is arranged at a side of the light-emitting layer away from the base plate and includes a light-filtering portion, a light-shielding portion, and an optical adjustment portion; an orthographic projection of the light-filtering portion on the base plate at least partially overlaps an orthographic projection of the light-emitting unit on the base plate, at least one optical adjustment portion is arranged between adjacent light-filtering portions, the optical adjustment portion at least partially contacts with the light-filtering portion, and a refractive index of the optical adjustment portion is less than a refractive index of the light-filtering portion; an orthographic projection of the light-shielding portion on the base plate is located within an orthographic projection of the optical adjustment portion on the base plate.

In one embodiment of the present application provides a display apparatus, including the display module according to any of the above implementation.

The display module according to embodiments of the present application includes the base plate, the light-emitting layer, and the light-filtering layer. The light-filtering layer includes the light-filtering portion, the light-shielding portion, and the optical adjustment portion. The orthographic projection of the light-filtering portion on the base plate at least partially overlaps the orthographic projection of the light-emitting unit on the base plate. The orthographic projection of the light-shielding portion on the base plate is located within the orthographic projection of the optical adjustment portion on the base plate. At least one optical adjustment portion is arranged between adjacent light-filtering portions, the optical adjustment portion at least partially contacts with the light-filtering portion, and the refractive index of the optical adjustment portion is less than the refractive index of the light-filtering portion. Therefore, light at a large viewing angle, when entering the optical adjustment portion from the light-filtering portion, is likely to be totally reflected at an interface where the light-filtering portion contacts the optical adjustment portion, but will not be absorbed by the light-shielding portion. Further, the light at the large viewing angle is converted into a front viewing angle, thereby improving light-emitting efficiency at a front viewing angle and reducing power consumption of the display module.

### BRIEF DESCRIPTION OF THE DRAWINGS

Features, advantages and technical effects of exemplary embodiments of the present application will be described below with reference to the accompanying drawings, which are not drawn to scale.

FIG. 1 shows a schematic cross-sectional view of a display module according to an embodiment of the present application;

FIG. 2 shows another schematic cross-sectional view of a display module according to an embodiment of the present application;

FIG. 3 shows another schematic cross-sectional view of a display module according to an embodiment of the present application;

FIG. 4 shows a schematic partial diagram of a display module according to an embodiment of the present application;

FIG. 5 shows another schematic partial diagram of a display module according to an embodiment of the present application;

FIG. 6 shows another schematic cross-sectional view of a display module according to an embodiment of the present application;

FIG. 7 is a schematic partial diagram of a display module according to an embodiment of the present application;

FIG. 8 shows another schematic cross-sectional view of a display module according to an embodiment of the present application;

FIG. 9 shows another schematic partial diagram of a display module according to an embodiment of the present application;

FIG. 10 shows yet another schematic cross-sectional view of a display module according to an embodiment of the present application;

FIG. 11 shows yet another schematic cross-sectional view of a display module according to an embodiment of the present application;

FIG. 12 shows a schematic flow diagram of a manufacturing method for a display module according to an embodiment of the present application;

FIGS. 13 to 20 show schematic diagrams of a manufacturing process of a display module according to an embodiment of the present application.

### REFERENCE NUMERALS

100, display module; 10, base plate; 20, light-emitting layer; 21, first electrode; 22, light-emitting unit; 22a, first light-emitting unit; 22b, second light-emitting unit; 22c, third light-emitting unit; 23, second electrode; 30, light-filtering layer; 31, light-filtering portion; 31a, first light-filtering portion; 31b, second light-filtering portion; 31c, third light-filtering portion; 32, light-shielding portion; 33, optical adjustment portion; 34, lens; 40, encapsulation layer; 50, pixel definition layer; 51, pixel definition portion; 52, pixel opening; 60, protection layer; 70, touch control layer; 71, insulation layer; 72, electrode layer.

### DETAILED DESCRIPTION

Features and exemplary embodiments of the present application will be described in detail below. Numerous specific details are set forth in the following detailed description to provide a thorough understanding of the present application. However, it will be apparent that the present application may be practiced without some of these specific details. The following description of the embodiments is merely intended to provide a better understanding of the present application by illustrating examples of the present application. In the accompanying drawings and the following description, at least some of well-known structures and techniques are not shown to avoid unnecessary obscurity of the present application. In addition, size of some structures may be exaggerated for clarity. Furthermore, the features, structures, or characteristics described below may be combined in one or more embodiments by any suitable manner.

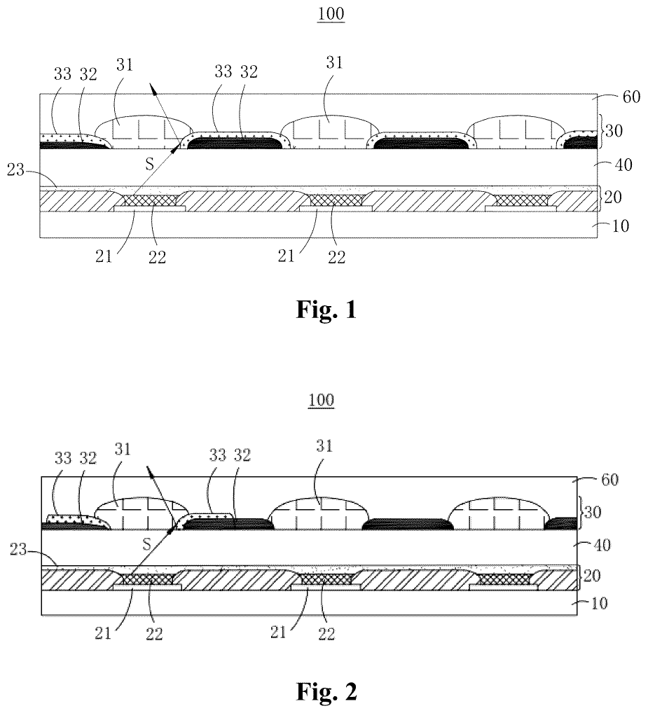

For a better understanding of the present application, a display module, a manufacturing method for a display module, and a display apparatus according to the embodiments of the present application will be described in detail below with reference to FIGS. 1 to 20.

The embodiments of the present application provide a display module, which may be an Organic Light Emitting Diode (OLED) display module, or other types of display panel, such as a Micro Light Emitting Diode (Micro-LED) display module or a Quantum Light Emitting Diode (QLED) display module.

As shown in FIG. 1, in one embodiment of the present application provides a display module 100, including a base plate 10, a light-emitting layer 20, and a light-filtering layer 30. The light-emitting layer 20 is arranged at one side of the base plate 10 and includes a plurality of light-emitting units 22. The light-filtering layer 30 is arranged at a side of the light-emitting layer 20 away from the base plate 10 and includes a light-filtering portion 31, a light-shielding portion 32, and an optical adjustment portion 33; an orthographic projection of the light-filtering portion 31 on the base plate 10 at least partially overlaps an orthographic projection of the light-emitting unit 22 on the base plate 10, at least one optical adjustment portion 33 is arranged between adjacent light-filtering portions 31, the optical adjustment portion 33 at least partially contacts with the light-filtering portion 31, and a refractive index of the optical adjustment portion 33 is less than a refractive index of the light-filtering portion 31; an orthographic projection of the light-shielding portion 32 on the base plate 10 is located within an orthographic projection of the optical adjustment portion 33 on the base plate 10.

The base plate 10 includes a substrate and an array layer. The substrate may be a flexible substrate made of materials such as Polyimide (PI), Polyethylene terephthalate (PET), and the like, and the display panel can be bent, or the substrate may be a rigid substrate made of materials such as glass, ceramic, and the like. A drive circuit for controlling the light-emitting layer 20 to emit light is provided in the array layer. The array layer is generally composed of inorganic film layers such as a metal layer, a semiconductor layer (an active layer), an insulation layer, and the like. By patterning these inorganic film layers, the drive circuit for controlling the light-emitting layer 20 to emit light can be formed. The specific circuit structure of the drive circuit may be implemented in various manners, which may not be repeated herein.

The light-emitting layer 20 includes a first electrode 21, a light-emitting unit 22, and a second electrode 23 that are stacked in sequence along a direction away from the base plate 10, and the first electrode 21, the light-emitting unit 22, and the second electrode 23 are stacked in sequence to form a sub-pixel. The light-emitting unit 22 may be formed by stacking various film layer structures. Exemplarily, the light-emitting unit 22 may include a hole inject layer (HIL), a hole transport layer (HTL), a light-emitting layer, an electron inject layer (EIL), and an electron transport layer (ETL). When the first electrode 21 and the second electrode 23 are energized, the first electrode 21 may be an anode, and the second electrode 23 may be a cathode. Electrons and holes respectively migrate from the electron transport layer and the hole transport layer to the light-emitting layer, and meet in the light-emitting layer to form excitons to excite light-emitting molecules, thereby generating visible light, to achieve the purpose of display. In other embodiments, a plurality of light-emitting units 22 may be further provided between the first electrode 21 and the second electrode 23, and a charge generation layer (CGL) is provided between the light-emitting units 22.

The display module 100 includes a plurality of pixel units, and each pixel unit may include three sub-pixels, i.e., a red sub-pixel, a green sub-pixel, and a blue sub-pixel. The light-emitting unit 22 of each sub-pixel includes a corresponding light-emitting material. Of course, sub-pixels of other colors may be further included. The orthographic projection of the light-filtering portion 31 on the base plate 10 at least partially overlaps the orthographic projection of the light-emitting unit 22 on the base plate 10. That is, a plurality of light-filtering portions 31 and a plurality of light-emitting units 22 are arranged in one-to-one correspondence, and the light-filtering portions 31 are configured to filter out light of other colors, to ensure that only light of a desired color passes through. For example, the light-filtering portion 31 above the light-emitting unit 22 of the red sub-pixel allows only red light to pass through, the light-filtering portion 31 above the light-emitting unit 22 of the green sub-pixel allows only green light to pass through, and the light-filtering portion 31 above the light-emitting unit 22 of the blue sub-pixel allows only blue light to pass through. Thus, each sub-pixel emits only light of a specific color when a current passes through a corresponding light-emitting unit 22, thereby forming a color image.

The orthographic projection of the light-shielding portion 32 on the base plate 10 is spaced apart from the orthographic projection of the light-emitting unit 22 on the base plate 10, and the light-shielding portion 32 may be a black matrix, which can reduce or prevent ambient light from entering an area between adjacent light-emitting units 22, and improve display interference, without affecting light emission of the light-emitting unit 22.

The orthographic projection of the light-shielding portion 32 on the base plate 10 is located within the orthographic projection of the optical adjustment portion 33 on the base plate 10, at least one optical adjustment portion 33 is arranged between adjacent light-filtering portions 31, and the optical adjustment portion 33 at least partially contacts with the light-filtering portion 31. As shown in FIG. 2, the optical adjustment portion 33 may be arranged only beside a light-filtering portion 31 of a light-emitting unit 22 of a certain color. For example, the light-emitting unit 22 of the blue sub-pixel may have high power consumption, and the optical adjustment portion 33 may be arranged beside the light-filtering portion 31 of the light-emitting unit 22 of the blue sub-pixel. Alternatively, as shown in FIG. 1, the optical adjustment portion 33 may be arranged beside each of the light-filtering portions 31 of all the light-emitting units 22.

There is a contact interface between the optical adjustment portion 33 and the light-filtering portion 31. The contact interface may be only a sidewall surface of the optical adjustment portion 33, or include the sidewall surface of the optical adjustment portion 33 and a part of an edge of a top surface of the optical adjustment portion 33.

“The orthographic projection of the light-shielding portion 32 on the base plate 10 is located within the orthographic projection of the optical adjustment portion 33 on the base plate 10” refers to: an outline of the orthographic projection of the light-shielding portion 32 on the base plate 10 is located within an outline of the orthographic projection of the optical adjustment portion 33 on the base plate 10. For example, the optical adjustment portion 33 is arranged at a side of the light-shielding portion 32 away from the light-emitting layer 20, and the optical adjustment portion 33 may fully cover the side of the light-shielding portion 32 away from the light-emitting layer 20, or may partially cover the side of the light-shielding portion 32 away from the light-emitting layer 20, for example, wrap only an edge of the light-shielding portion 32. Furthermore, the optical adjustment portion 33 may be arranged between the light-shielding portion 32 and the light-emitting layer 20.

Since the refractive index of the light-filtering portion 31 is generally high, a total reflection phenomenon occurs between the optical adjustment portion 33 and the light-filtering portion 31 by providing the optical adjustment portion 33 with a lower refractive index. Exemplarily, light S at a large viewing angle, when entering the optical adjustment portion 33 from the light-filtering portion 31, is likely to be totally reflected at an interface where the light-filtering portion 31 contacts the optical adjustment portion 33, but will not be absorbed by the light-shielding portion 32. Further, the light S at the large viewing angle is converted into a front viewing angle. That is, the light S at a large viewing angle that would have been absorbed by the light-shielding portion 32 originally is converted and utilized, thereby improving light-emitting efficiency at the front viewing angle and reducing power consumption of the display module 100.

The “large viewing angle” refers to a side viewing angle that deviates from the front viewing angle by a large amount, e.g., 30 degrees to 89 degrees. The “total reflection” refers to a phenomenon in which light is totally reflected at an interface. When the light is incident from an optically denser medium into an optically thinner medium, the angle of refraction will exceed 90 degrees under a condition that the angle of incidence is greater than the critical angle, which means that the light cannot pass through the interface but is totally reflected back into the incident medium. In this case, all the energy of the light at the interface is reflected and no light is transmitted.

In view of the above, in the embodiments of the present application, Color Filter (CF) technology is utilized to form a Micro Lens Array (MLA) by adding an optical adjustment portion 33 with a low refractive index in cooperation with the light-filtering portion 31, to convert light at a large viewing angle into a front viewing angle, thereby improving light-emitting efficiency at the front viewing angle and reducing power consumption of the display module 100.

In addition, in the present embodiment, the Micro Lens Array (MLA) can be formed by simply adding the optical adjustment portion 33 with a low refractive index, without additionally manufacturing a film layer with a high refractive index, which simplifies the process, saves the number of masks, and reduces the cost. Furthermore, in the present embodiment, only the optical adjustment portion 33 is required, without additionally adding other film layers, to form the Micro Lens Array, which can further reduce the loss of light.

In one embodiment, the display module 100 may further include an encapsulation layer 40, which is located between the light-emitting layer 20 and the light-filtering layer 30. The encapsulation layer 40 covers the light-emitting layer 20 for protecting the light-emitting layer 20 against attack by water vapor and oxygen. The encapsulation layer 40 may be a thin film encapsulation layer 40, and may include, for example, an inorganic encapsulation layer, an organic encapsulation layer, and an inorganic encapsulation layer that are stacked to provide blocking to water vapor and oxygen.

In some embodiments, the orthographic projection of the optical adjustment portion 33 on the base plate 10 is spaced apart from the orthographic projection of the light-emitting unit 22 on the base plate 10, thereby ensuring that the light-filtering portion 31 is directly above the light-emitting unit 22 without affecting light-emitting efficiency at a front viewing angle of the light-emitting unit 22.

Referring to FIGS. 1 to 3, in some embodiments, in a direction parallel to the base plate 10, a difference between a distance from the light-filtering portion 31 to the optical adjustment portion 33 and a distance from the light-filtering portion 31 to an edge of the light-shielding portion 32 is L, and L satisfies: L>0 μm.

“The difference between the distance from the light-filtering portion 31 to the optical adjustment portion 33 and the distance from the light-filtering portion 31 to the edge of the light-shielding portion 32” refers to a distance between an edge of the optical adjustment portion 33 in the direction parallel to the base plate 10 and the edge of the light-shielding portion 32 in the direction parallel to the base plate 10. Furthermore, the light-filtering portion 31, the optical adjustment portion 33, and the light-shielding portion 32 are discussed based on the same light-emitting unit 22, that is, the light-filtering portion 31, optical adjustment portion 33, and light-shielding portion 32 refer to ones that correspond to the same light-emitting unit 22 and are located above the same light-emitting unit 22. Exemplarily, the optical adjustment portion 33 may be arranged above the light-shielding portion 32 and cover a sidewall surface of the light-shielding portion 32. Alternatively, the optical adjustment portion 33 may be arranged below the light-shielding portion 32, and the edge of the optical adjustment portion 33 may protrude outward with respect to the edge of the light-shielding portion 32. In the present embodiment, since the edge of the optical adjustment portion 33 protrudes with respect to the edge of the light-shielding portion 32, and the protruding portion replaces an original part of the light-shielding portion 32, the absorption of the light of a large viewing angle by the light-shielding portion 32 is reduced, and a contact area between the optical adjustment portion 33 and the light-filtering portion 31 is increased. Therefore, more light of a large viewing angle can be totally reflected at the contact interface, thereby further improving light-emitting efficiency at a front viewing angle and reducing power consumption.

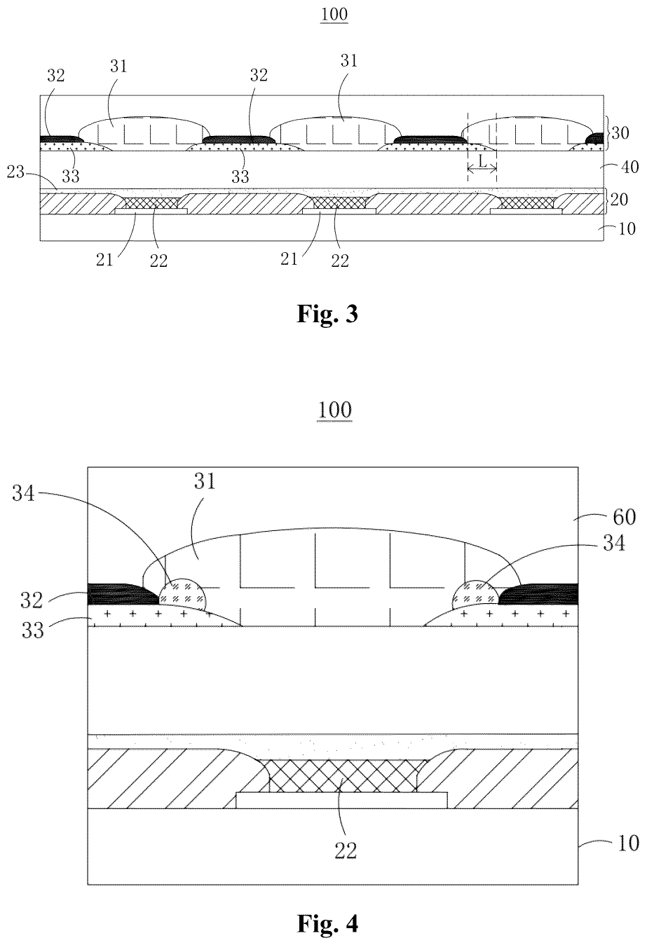

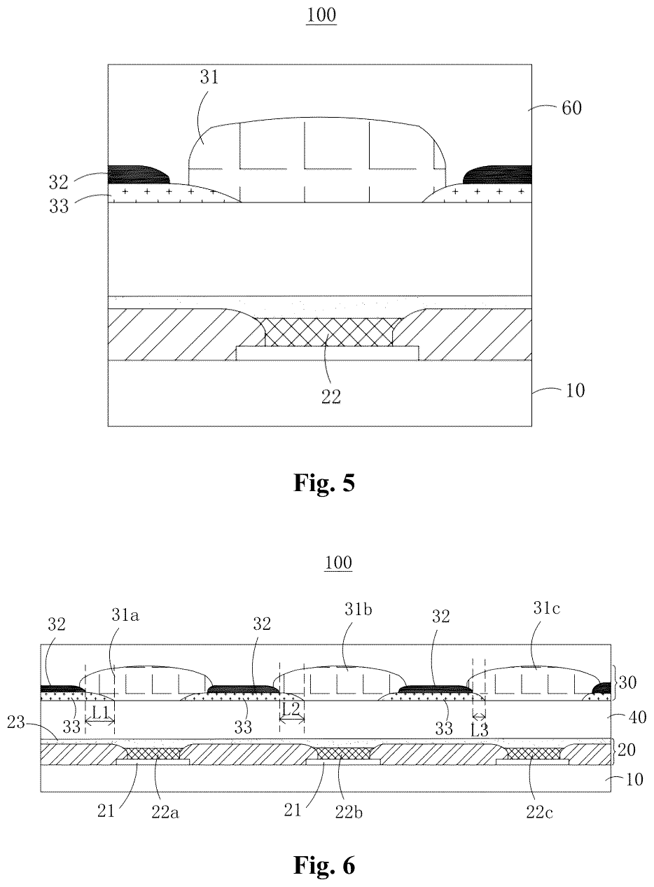

In one embodiment, as shown in FIG. 3, the light-filtering portion 31 may cover the entire protruding edge of the optical adjustment portion 33 with respect to the light-shielding portion 32. As shown in FIG. 4, a lens 34 may be further provided at a side of the optical adjustment portion 33 away from the light-emitting layer 20, the lens 34 is arranged close to the light-shielding portion 32, and the light-filtering portion 31 covers both the optical adjustment portion 33 and the lens 34, to further improve light-emitting efficiency of the light-emitting unit 22. Alternatively, as shown in FIG. 5, only a part of the protruding edge of the optical adjustment portion 33 with respect to the light-shielding portion 32 may be covered, that is, the light filtering part 31 and the light-shielding portion 32 are not in contact, having a gap therebetween.

As shown in FIG. 3, in some embodiments, in the direction parallel to the base plate 10, a length for which the optical adjustment portion 33 protrudes with respect to the light-shielding portion 32 is L, and L satisfies: 3 μm≤L≤6 μm.

If L is too small, more light of a large viewing angle that would have been absorbed by the light-shielding portion 32 cannot be efficiently converted and utilized to improve light-emitting efficiency. If L is too large, the effect of the light-shielding portion 32 is affected, and ambient light cannot be reduced or prevented from entering the area between adjacent light-emitting units 22, and display interference cannot be improved, while light emission of the light-emitting units 22 can be affected. A range of the length L for which the optical adjustment portion 33 protrudes with respect to the light-shielding portion 32 in the present embodiment is reasonable, and can not only improve light-emitting efficiency, but also reduce the reflectance of ambient light and the reflectance of an interior of the display module 100.

As shown in FIG. 6, in some embodiments, the light-emitting layer 20 includes a first light-emitting unit 22a, a second light-emitting unit 22b, and a third light-emitting unit 22c that are different from one another in color, the light-filtering layer 30 includes a first light-filtering portion 31a, a second light-filtering portion 31b, and a third light-filtering portion 31c, an orthographic projection of the first light-filtering portion 31a on the base plate 10 at least partially overlaps that of the first light-emitting unit 22a, an orthographic projection of the second light-filtering portion 31b on the base plate 10 at least partially overlaps that of the second light-emitting unit 22b, and an orthographic projection of the third light-filtering portion 31c on the base plate 10 at least partially overlaps that of the third light-emitting unit 22c. Exemplarily, the first light-filtering portion 31a is located directly above the first light-emitting unit 22a, the second light-filtering portion 31b is located directly above the second light-emitting unit 22b, and the third light-filtering portion 31c is located directly above the third light-emitting unit 22c. Light emitted by the first light-emitting unit 22a passes through the first light-filtering portion 31a to be emitted from a light-emitting side of the display module 100, light emitted by the second light-emitting unit 22b passes through the second light-filtering portion 31b to be emitted from the light-emitting side of the display module 100, and light emitted by the third light-emitting unit 22c passes through the third light-filtering portion 31c to be emitted from the light-emitting side of the display module 100.

In a direction parallel to the base plate 10, a difference between a distance from the first light-filtering portion 31a to an edge of the optical adjustment portion 33 and a distance from the first light-filtering portion 31a to an edge of the light-shielding portion 32 is L1, a difference between a distance from the second light-filtering portion 31b to the edge of the optical adjustment portion 33 and a distance from the second light-filtering portion 31b to the edge of the light-shielding portion 32 is L2, and a difference between a distance from the third light-filtering portion 31c to the edge of the optical adjustment portion 33 and a distance from the third light-filtering portion 31c to the edge of the light-shielding portion 32 is L3, and L1, L2 and L3 satisfy: L1>L2, and L1>L3; in which light-emitting efficiency of the first light-emitting unit 22a is less than light-emitting efficiency of the second light-emitting unit 22b, and less than light-emitting efficiency of the third light-emitting unit 22c.

Since light-emitting materials for light-emitting units 22 of different colors are different, light-emitting efficiencies of the light-emitting units 22 of different colors are also different, and thus power consumption is also different. Exemplarily, the first light-emitting unit 22a is a blue light-emitting unit 22, the second light-emitting unit 22b is a red light-emitting unit 22, and the third light-emitting unit 22c is a green light-emitting unit 22. Compared to materials for the red light-emitting unit 22 and the green light-emitting unit 22, electron-photon energy conversion efficiency of a light-emitting material for the blue light-emitting unit 22 is lower, resulting in a lower light-emitting efficiency of the blue light-emitting unit 22, and thus power consumption of the blue light-emitting unit 22 is the highest. In the embodiments of the present application, the first light-emitting unit 22a with the lowest light-emitting efficiency is configured such that: the difference L1 between the distance from the first light-filtering portion 31a to the edge of the optical adjustment portion 33 and the distance from the first light-filtering portion 31a to the edge of the light-shielding portion 32 is the longest, and light-emitting efficiency at a front viewing angle of the first light-emitting unit 22a can be improved to the most extent, thereby reducing power consumption of the display module 100.

In some embodiments, L1, L2, and L3 satisfy: L1>L2>L3; in which white light brightness ratio of the third light-emitting unit 22c is greater than white light brightness ratio of the first light-emitting unit 22a, and greater than white light brightness ratio of the second light-emitting unit 22b.

The “white light brightness ratio” refers to, when the first light-emitting unit 22a, the second light-emitting unit 22b, and the third light-emitting unit 22c are mixed into white light and a total brightness is 100%, a ratio at which a light-emitting brightness of each light-emitting unit 22 contribute to the white light. Exemplarily, if the first light-emitting unit 22a is a blue light-emitting unit 22, the second light-emitting unit 22b is a red light-emitting unit 22, and the third light-emitting unit 22c is a green light-emitting unit 22, the white light brightness ratio of the third light-emitting unit 22c is the greatest, For example, the white light brightness ratio of the third light-emitting unit 22c is 60%, and the white light brightness ratio of the first light-emitting unit 22a and the white light brightness ratio of the second light-emitting unit 22b are each 20%.

In the embodiments of the present application, the third light-emitting unit 22c with the greatest white light brightness ratio is configured such that: the difference L3 between the distance from the third light-filtering portion 31c to the edge of the optical adjustment portion 33 and the distance from the third light-filtering portion 31c to the edge of the light-shielding portion 32 is the shortest, and a proportion at which light at a large viewing angle is converted into light at a front viewing angle can be reduced with respect to the first light-emitting unit 22a and the second light-emitting unit 22b, thereby ensuring that, on the basis of improving light-emitting efficiency, light emitted at a large viewing angle by the third light-emitting unit 22c still takes a larger proportion, to further ensure that color deviation is less likely to occur when the display module 100 is viewed at a large viewing angle.

In some embodiments, the orthographic projection of the optical adjustment portion 33 on the base plate 10 partially overlaps the orthographic projection of the light-filtering portion 31 on the base plate 10. That is, the light-filtering portion 31 wraps the sidewall surface of the optical adjustment portion 33, and the light-filtering portion 31 may further wrap a part of the top surface of the optical adjustment portion 33. Since the optical adjustment portion 33 and the light-filtering portion 31 in the embodiments of the present application are arranged partially overlapping, and not only the contact interface between the optical adjustment portion 33 and the light-filtering portion 31 can be increased, but also space can be saved, which reduces spacing between various sub-pixels, thereby improving light-emitting efficiency of the display module 100.

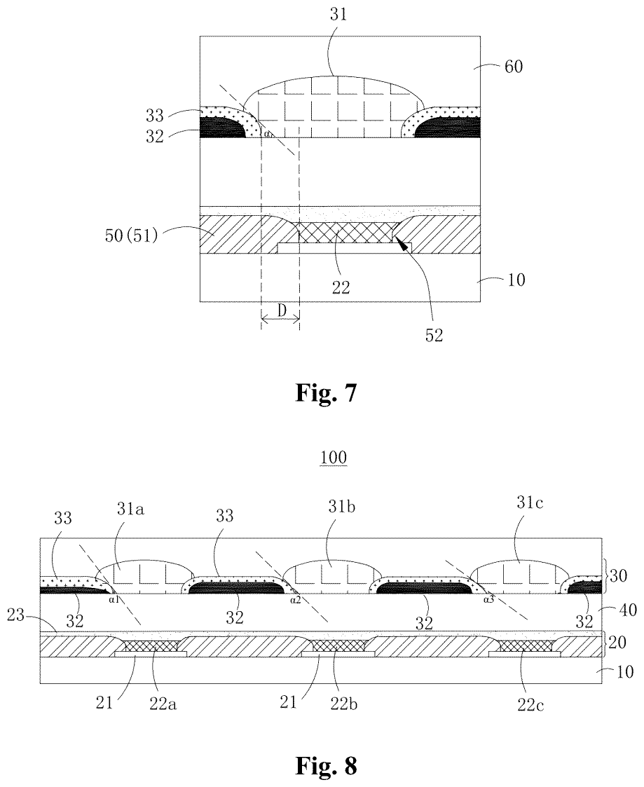

As shown in FIG. 7, in some embodiments, an angle between a sidewall surface of the optical adjustment portion 33 and a plane in a direction parallel to the base plate 10 is α, and α satisfies: 60°≤α≤90°. The sidewall surface of the optical adjustment portion 33 may be an inclined surface, or may be a vertical surface perpendicular to the base plate 10, or may be a curved surface. Under a condition that the sidewall surface is a curved surface, the angle α is an angle between a tangent of the curved surface and the plane in the direction parallel to the base plate 10. The value of α determines whether the light is emitted mainly at a side viewing angle or a front viewing angle when the light is totally reflected at the contact interface between the optical adjustment portion 33 and the light-filtering portion 31. If α is too small, when light is totally reflected at the contact interface between the optical adjustment portion 33 and the light-filtering portion 31, most light is emitted at a side viewing angle. In the embodiments of the present application, α is 60° to 90°. Most light at a large viewing angle, when entering the optical adjustment portion 33 from the light-filtering portion 31, is totally reflected at the contact interface between the optical adjustment portion 33 and the light-filtering portion 31, and will be emitted at a front viewing angle, and light-emitting efficiency at a front viewing angle can be further improved.

Further, a satisfies: 70°≤α≤80°. If α is too large, for example, 80°≤α≤90°, a part of the light may still be emitted at a side viewing angle when the light is totally reflected at the contact interface between the optical adjustment portion 33 and the light-filtering portion 31. Herein, α is configured such that 70°≤α≤80°, which can further ensure that more light is emitted at a front viewing angle when total reflection occurs at the contact interface between the optical adjustment portion 33 and the light-filtering portion 31, thereby improving light-emitting efficiency at a front viewing angle.

In some embodiments, the light-emitting layer 22 includes a first light-emitting unit 22a, a second light-emitting unit 22b, and a third light-emitting unit 22c that are different from one another in color, the light-filtering layer 30 includes a first light-filtering portion 31a, a second light-filtering portion 31b, and a third light-filtering portion 31c, an orthographic projection of the first light-filtering portion 31a on the base plate 10 at least partially overlaps that of the first light-emitting unit 22a, an orthographic projection of the second light-filtering portion 31b on the base plate 10 at least partially overlaps that of the second light-emitting unit 22b, and an orthographic projection of the third light-filtering portion 31c on the base plate 10 at least partially overlaps that of the third light-emitting unit 22c.

As shown in FIG. 8, an angle between a sidewall surface of the optical adjustment portion 33 facing the first light-filtering portion 31a and a plane in a direction parallel to the base plate 10 is α1, an angle between a sidewall surface of the optical adjustment portion 33 facing the second light-filtering portion 31b and the plane in the direction parallel to the base plate 10 is α2, an angle between a sidewall surface of the optical adjustment portion 33 facing the third light-filtering portion 31c and the plane in the direction parallel to the base plate 10 is α3. Herein, α1, α2, and α3 satisfy: |α1-β|<α2-β|, and |α1-β|<|α3-β|, in which β is a critical angle at which total reflection of light occurs at an interface where the optical adjustment portion 33 contacts the light-filtering portion 31; and light-emitting efficiency of the first light-emitting unit 22a is less than light-emitting efficiency of the second light-emitting unit 22b, and less than light-emitting efficiency of the third light-emitting unit 22c.

Since light-emitting materials for light-emitting units 22 of different colors are different, light-emitting efficiencies of the light-emitting units 22 of different colors are also different, and thus power consumption is also different. Exemplarily, the first light-emitting unit 22a is a blue light-emitting unit 22, the second light-emitting unit 22b is a red light-emitting unit 22, and the third light-emitting unit 22c is a green light-emitting unit 22. Compared to materials for the red light-emitting unit 22 and the green light-emitting unit 22, electron-photon energy conversion efficiency of a light-emitting material for the blue light-emitting unit 22 is lower, resulting in a lower light-emitting efficiency of the blue light-emitting unit 22, and thus power consumption of the blue light-emitting unit 22 is the highest.

The critical angle for total reflection is determined by a difference in refractive index when light is incident from one optically denser medium into another optically thinner medium. The light, when being incident from the optically denser medium into the optically thinner medium, is refracted. At a particular angle, when the angle of refraction is equal to 90 degrees, the light will be totally reflected and returns to the original medium without passing through the interface. The critical angle is a maximum angle of incidence at which total reflection of light occurs and can be calculated by Snell's law. Snell's law indicates that when the light passes through the interface between two media, the angle of incidence (θᵢ) and the angle of refraction (θᵣ) satisfy: nᵢ*sin (θᵢ)=nᵣ*sin (θᵣ). Herein, nᵢ and nᵣ are the refractive index of the optically denser medium and the refractive index of the optically thinner medium, respectively, θᵢ is the angle of incidence, and θᵣ is the angle of refraction. When the angle of refraction (θᵣ) is equal to 90 degrees, i.e., sin (θᵣ)=1, it can be obtained according to Snell's law: nᵢ*sin (θᵢ)=nᵣ*1, i.e., sin (θᵢ)=nᵣ/nᵢ, in which θᵢ is the critical angle at which total reflection occurs. When the angle of incidence is greater than the critical angle, the total reflection of light will occur. When the angle of incidence is less than the critical angle, refraction of light will occur.

In the embodiments of the present application, the critical angle at which total reflection of light occurs at the interface where the optical adjustment portion 33 contacts the light-filtering portion 31 is β. In the embodiments of the present application, the first light-emitting unit 22a with the lowest light-emitting efficiency is configured such that: the difference between the angle α1 between the sidewall surface of the optical adjustment portion 33 facing the first light-filtering portion 31a and the plane in the direction parallel to the base plate 10 and the critical angle β is minimum. That is, α1 is set to be closest to the critical angle β, and more light, when totally reflection occurs at the contact interface between the optical adjustment portion 33 and the first light-filtering portion 31a, is emitted at a front viewing angle, and light-emitting efficiency at a front viewing angle of the first light-emitting unit 22a can be improved to the most extent, thereby reducing power consumption of the display module 100.

In some embodiments, α1, α2, and α3 satisfy: |α1-α3|>|α1-α2|, in which white light brightness ratio of the third light-emitting unit 22c is greater than white light brightness ratio of the first light-emitting unit 22a, and greater than white light brightness ratio of the second light-emitting unit 22b.

Exemplarily, if the first light-emitting unit 22a is a blue light-emitting unit 22, the second light-emitting unit 22b is a red light-emitting unit 22, and the third light-emitting unit 22c is a green light-emitting unit 22, the white light brightness ratio of the third light-emitting unit 22c is the greatest, For example, the white light brightness ratio of the third light-emitting unit 22c is 60%, and the white light brightness ratio of the first light-emitting unit 22a and the white light brightness ratio of the second light-emitting unit 22b are each 20%. Since the white light brightness ratio of the third light-emitting unit 22c is the highest, and a difference between α1 and α3 is set to be greater than a difference between α1 and α2, which may indicate that a difference value between α1 and the critical angle β at which total reflection occurs is the greatest, light that is totally reflected at the interface where the optical adjustment portion 33 contacts the third light-filtering portion 31c takes the lowest proportion, light emitted at a large viewing angle by the third light-emitting unit 22c still takes a larger proportion, to ensure that color deviation is less likely to occur when the display module 100 is viewed at a large viewing angle.

As shown in FIG. 7, in some embodiments, the light-emitting layer 20 further includes a pixel definition layer 50, the pixel definition layer 50 has a pixel opening 52, and the light-emitting unit 22 is located in the pixel opening 52. Specifically, the pixel definition layer 50 includes a pixel definition portion 51 and the pixel opening 52 enclosed and formed by the pixel definition portion 51. The pixel definition layer 50 may include an inorganic material or a polymer material. For example, an inorganic material such as silicon oxide, silicon nitride, silicon, and the like, or a polyimide polymer material may be used. A plurality of light-emitting units 22 may be arranged in one-to-one correspondence with a plurality of pixel openings 52, or the light-emitting units 22 may be arranged in correspondence with one pixel opening 52, thereby reducing the phenomenon of mutual interference between sub-pixels.

The orthographic projection of the optical adjustment portion 33 on the base plate 10 is located within an orthographic projection of the pixel definition layer 50 on the base plate 10. That is, the edge of the optical adjustment portion 33 is located within an edge of the pixel definition portion 51, or the edge of the optical adjustment portion 33 is level with the edge of the pixel definition portion 51, and the optical adjustment portion 33 will not block the light-emitting unit 22, and light emitted at a front viewing angle by the light-emitting unit 22 is not affected.

In some embodiments, in a direction parallel to the base plate 10, a distance between the optical adjustment portion 33 and a sidewall surface of the pixel opening 52 is D, and D satisfies: 0 μm≤D≤5 μm.

The “distance between the optical adjustment portion 33 and the sidewall surface of the pixel opening 52” refers to: a distance between the edge of the optical adjustment portion 33 and the edge of the pixel definition portion 51. If D is too large, more light at a large viewing angle that would have been absorbed originally by the light-shielding portion 32 cannot be effectively converted and utilized to improve light-emitting efficiency. A range of the distance D between the optical adjustment portion 33 and the sidewall surface of the pixel opening 52 in the present embodiment is reasonable, and more light at a large viewing angle can be efficiently converted and utilized to improve light-emitting efficiency.

In some embodiments, the display module 100 further includes a protection layer 60 arranged at a side of the light-filtering layer 30 away from the base plate 10. The protection layer 60 can protect the light-filtering layer 30 against damages from external factors, such as scratches, abrasion, and chemical corrosion on a surface of the light-filtering layer 30, and prolong the service life of the light-filtering layer 30.

In some embodiments, a refractive index of the protection layer 60 is less than the refractive index of the light-filtering portion. For example, an existing optical glue layer (OC) may be used.

In some embodiments, the optical adjustment portion 33 includes an organic material. Exemplarily, the optical adjustment portion 33 may be made of organic polymer, fluoropolymer, and other materials, such as polyimide, polymethyl methacrylate, and the like. Since an organic material is used for the optical adjustment portion 33 in the embodiments of the present application, the optical adjustment portion 33 can be formed as a film layer with a greater thickness, without adding other film layers to heighten the optical adjustment portion 33 and form an interface for contacting the light-filtering portion 31, to convert a part of light at a large viewing angle into light at a front viewing angle, which not only simplifies the process, saves the number of masks, and reduces the cost, but also reduces the loss of light relative to a display module 100 requiring other film layers to heighten the optical adjustment portion 33. In addition, the bending performance can be improved, and the problem of peeling of film layers when bending, which affects display effects, can be avoided by using an organic material.

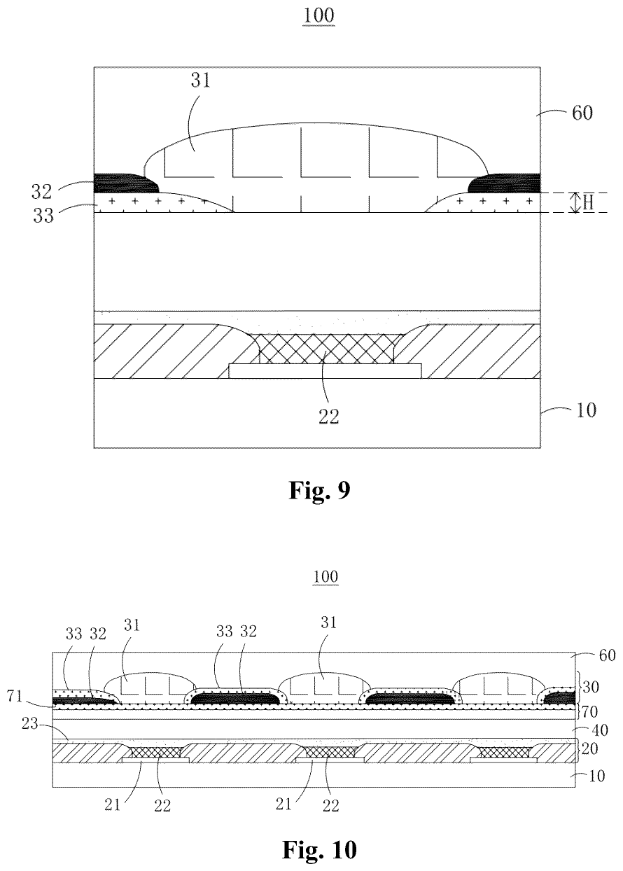

As shown in FIG. 9, in some embodiments, a thickness of the optical adjustment portion 33 is H, and H satisfies: 1.5 μm≤H≤5 μm., to ensure that the optical adjustment portion 33 has a greater thickness, which increases an area of the contact interface between the optical adjustment portion 33 and the light-filtering portion 31, and more light at a large viewing angle can be totally reflected at the contact interface.

In some embodiments, the refractive index of the optical adjustment portion 33 is n1, and n1 satisfies: n1≤1.55. If the refractive index of the optical adjustment portion 33 is too large, total reflection of light can occur only when the critical angle of incidence at the contact interface between the optical adjustment portion 33 and the light-filtering portion 31 is very large. In the embodiments of the present application, n1 is configured such that: n1≤1.55, facilitating total reflection of light at a large viewing angle at the contact interface between the optical adjustment portion 33 and the light-filtering portion 31.

Further, 1.4≤n1≤1.55. If the refractive index of the optical adjustment portion 33 is too small, a range of optional materials for the optical adjustment portion 33 is limited. The range of the refractive index of the optical adjustment portion 33 in the embodiments of the present application is reasonable, which can not only ensure that the range of the optional materials for the optical adjustment portion 33 is greater, but also facilitate total reflection of light at a large viewing angle at the contact interface between the optical adjustment portion 33 and the light-filtering portion 31. For example, n1 may be 1.4, 1.42, 1.45, 1.5, or 1.55.

In some embodiments, the refractive index of the light-filtering portion 31 is n2, and n2 satisfies: n2≥1.6. A difference between the refractive index of the optical light-filtering portion 31 and the refractive index of the optical adjustment portion 33 in the embodiments of the present application is greater, further facilitating total reflection of light at a large viewing angle at the contact interface between the optical adjustment portion 33 and the optical light-filtering portion 31. For example, n2 may be 1.6, 1.65, 1.68, 1.72, 1.8, and the like.

As shown in FIG. 10, in some embodiments, the optical adjustment portion 33 is arranged at a side of the light-shielding portion 32 away from the base plate 10. The light-shielding portion 32 may be manufactured first, and then the optical adjustment portion 33 may be manufactured.

In some embodiments, the optical adjustment portion 33 wraps a sidewall surface of the light-shielding portion 32, which can increase a contact area between the optical adjustment portion 33 and the light filtering part 31.

In some embodiments, the display module 100 further includes a touch control layer 70 arranged between the light-emitting layer 20 and the light-filtering layer 30, the touch control layer 70 includes an insulation layer 71, and a material of the optical adjustment portion 33 is the same as a material of the insulation layer 71.

The touch control layer 70 is a transparent layer for receiving a user's touch input. It is located at a top of the display panel, can realize touch interaction and input, and allows the user to control the display apparatus by directly touching the screen. The insulation layer 71 in the touch control layer 70 can serve to isolate a touch input signal. When the user touches the screen, the touch input signal (such as a charge) is sensed and transmitted to the touch control layer 70. The insulation layer 71, by its insulation properties, confines the touch input signal to a particular area, avoiding incorrect conduction and interference of the signal. The presence of the insulation layer 71 may further improve touch sensitivity, which prevents excessive spreading and leakage of the touch input signal, and the touch control layer can more accurately detect and interpret the user's touch action. In a capacitive touch screen, the insulation layer 71 further helps to reduce mutual capacitive interference. When multiple touch points exist simultaneously, the insulation layer 71 can prevent current interference between different touch areas, improving accuracy and reliability of multi-touch. The insulation layer 71 further helps to ensure proper transmission of the touch input signal. It provides a reliable dielectric environment, prevents charge loss and leakage, and ensures that the touch control layer can accurately sense and resolve the touch control input.

The material of the optical adjustment portion 33 in the embodiments of the present application is the same as the material of the insulation layer 71, facilitating manufacturing process and reducing the cost.

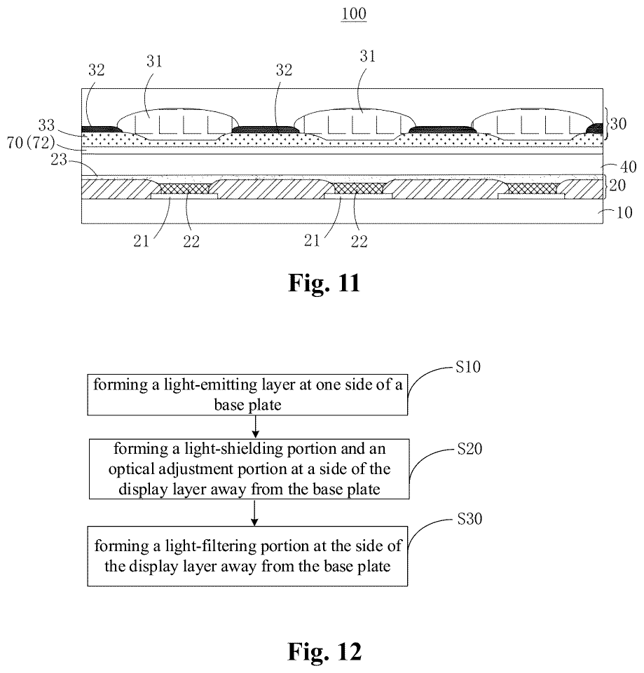

As shown in FIG. 11, in some embodiments, the optical adjustment portion 33 is arranged between the light-emitting layer 20 and the light-shielding portion 32. The optical adjustment portion 33 may be manufactured first, and then the light-shielding portion 32 may be manufactured.

In one embodiment, the display module 100 further includes a touch control layer 70 arranged between the light-emitting layer 20 and the light-filtering layer 30, and the optical adjustment portion 33 is reused as an insulation layer 71 in the touch control layer 70. The insulation layer 71 and the optical adjustment portion 33, when being manufactured, may be formed by directly using one mask, the same process method, and the same material. With respect to separate manufacturing of the insulation layer 71 and the optical adjustment portion 33, one mask is saved in the embodiments of the present application, which simplifies process steps, reduces the cost, and improves production efficiency.

As shown in FIG. 12, one embodiment of the present application provides a manufacturing method for a display module 100, including S10 to S30.

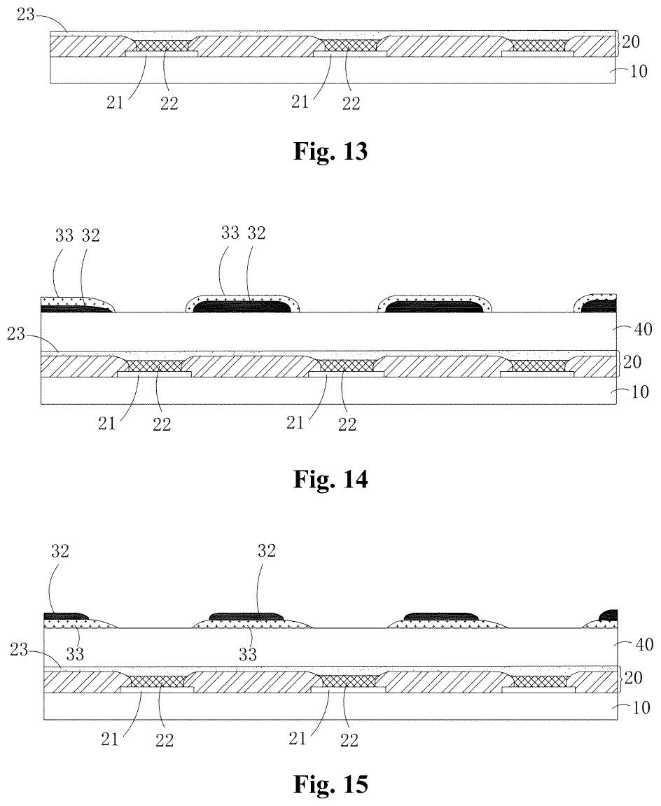

S10, forming a light-emitting layer 20 at one side of the base plate 10, as shown in FIG. 13.

The light-emitting layer 20 includes a plurality of light-emitting units 22.

S20, forming a light-shielding portion 32 and an optical adjustment portion 33 a side of the light-emitting layer 20 away from the base plate 10, as shown in FIGS. 14 and 15.

The light-shielding portion 32 and the optical adjustment portion 33 may be manufactured and formed by a photolithography process. An orthographic projection of the light-shielding portion 32 on the base plate 10 is located within an orthographic projection of the optical adjustment portion 33 on the base plate 10.

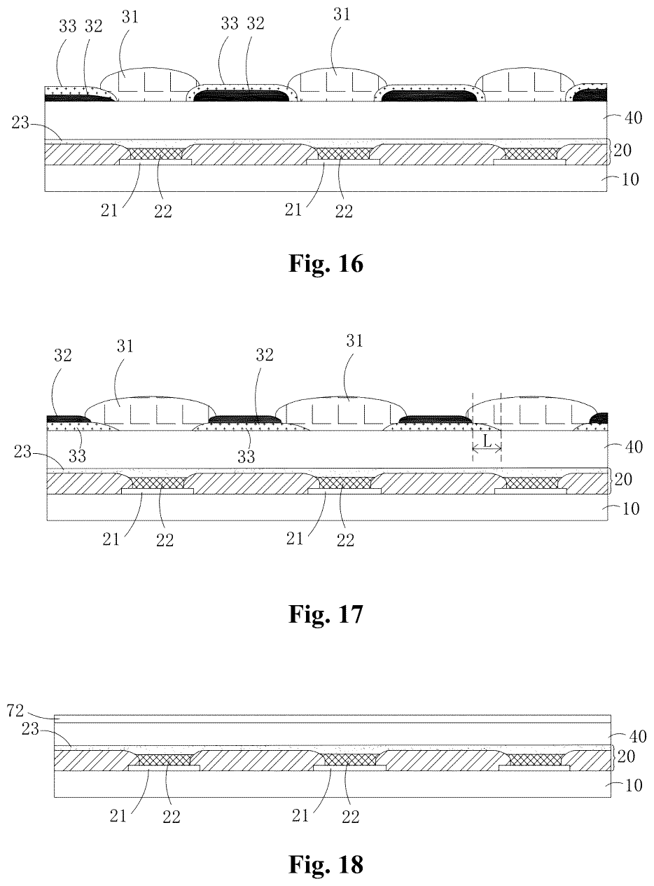

S30, forming a light-filtering portion 31 at the side of the light-emitting layer 20 away from the base plate 10, as shown in FIGS. 16 and 17.

An orthographic projection of the light-filtering portion 31 on the base plate 10 at least partially overlaps an orthographic projection of the light-emitting unit 22 on the base plate 10, at least one optical adjustment portion 33 is arranged between adjacent light-filtering portions 31, the optical adjustment portion 33 at least partially contacts with the light-filtering portion 31, and a refractive index of the optical adjustment portion 33 is less than a refractive index of the light-filtering portion 31.

In view of the above, in the embodiments of the present application, Color Filter (CF) technology is utilized to form a Micro Lens Array (MLA) by adding an optical adjustment portion 33 with a low refractive index in cooperation with the light-filtering portion 31, to convert light at a large viewing angle into a front viewing angle, thereby improving light-emitting efficiency at a large viewing angle and reducing power consumption of the display module 100. In addition, the Micro Lens Array (MLA) can be formed by simply adding the optical adjustment portion 33 with a low refractive index, without additionally manufacturing a film layer with a high refractive index, which simplifies the process, saves the number of masks, and reduces the cost. Furthermore, in the present embodiment, only the optical adjustment portion 33 is required, without additionally adding other film layers, to form the Micro Lens Array, which can further reduce the loss of light.

In some embodiments, the forming the light-shielding portion 32 and the optical adjustment portion 33 at the side of the light-emitting layer 20 away from the base plate 10 includes: forming the light-shielding portion 32 at the side of the light-emitting layer 20 away from the base plate 10; and forming the optical adjustment portion 33 at a side of the light-shielding portion 32 away from the base plate 10; or forming the optical adjustment portion 33 at the side of the light-emitting layer 20 away from the base plate 10; and forming the light-shielding portion 32 at a side of the optical adjustment portion 33 away from the base plate 10. That is, the order in which the light-shielding portion 32 and the optical adjustment section 33 are manufactured is not limited.

In some embodiments, the forming the light-shielding portion 32 and the optical adjustment portion 33 at the side of the light-emitting layer 20 away from the base plate 10 includes S21 to S23.

S21, forming an electrode layer 72 of a touch control layer 70 at the side of the light-emitting layer 20 away from the base plate 10, as shown in FIG. 18.

The electrode layer 72 includes a plurality of touch control electrodes, and the touch control electrodes can be used for realizing the touch control function of the display module 100. In a mutual-capacitance touch control display module 100, a touch control electrode may be used as a mutual-capacitance touch control electrode. For example, a touch control transmitting electrode receives a touch control signal through a touch control signal line, to form a mutual capacitance with a touch control receiving electrode. A touch point is determined by detecting a change in the mutual capacitance. In a self-capacitance touch display module 100, a touch control electrode may be used as a self-capacitance touch control electrode, which receives a touch control signal through a touch control signal line, and an induction signal generated due to a self-capacitance change when a touch point is detected is transmitted to a touch detection circuit through the touch control signal line.

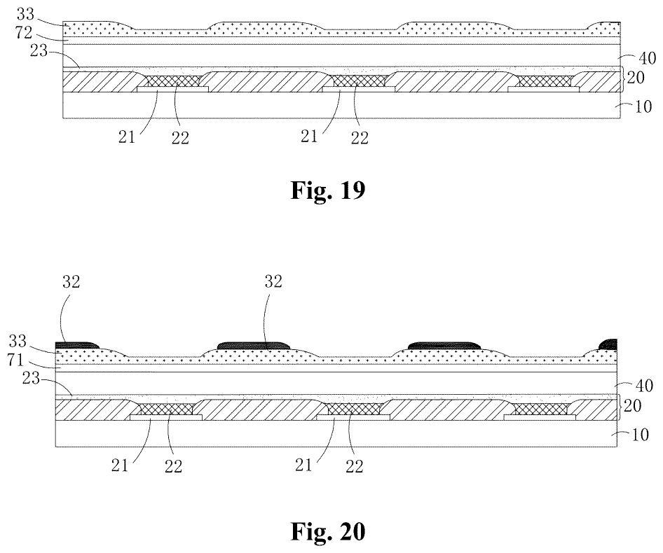

S22, forming the optical adjustment portion 33 at a side of the electrode layer 72 away from the base plate 10, as shown in FIG. 19.

The optical adjustment portion 33 is reused as an insulation layer 71 of the touch control layer 70. One mask, the same process method, and the same material may be directly used for forming. With respect to separate manufacturing of the insulation layer 71 and the optical adjustment portion 33, one mask is saved in the embodiments of the present application, which simplifies process steps, reduces the cost, and improves production efficiency.

S23, forming the light-shielding portion 32 at the side of the optical adjustment portion 33 away from the base plate 10, as shown in FIG. 20.

In one embodiment of the present application provides a display apparatus, including the display module 100 according to any of the above implementation, or being manufactured by the manufacturing method according to any of the above implementation. The display apparatus adopts all the technical solutions for all the above embodiments, and thus has at least all the advantageous effects brought by the technical solutions for the above embodiments, which is not repeated herein.

The display apparatus may be any device having a display function, and may be, for example, a mobile device such as a mobile phone, a tablet computer, a notebook computer, a palm computer, an electronic equipment of vehicle, a wearable device, an ultra-mobile personal computer (UMPC), a netbook, or a personal digital assistant (PDA), or a non-mobile device such as a personal computer (PC), a television (TV), a teller machine, or a self-service machine.

The above embodiments are exemplary and not limiting. Different technical features in different embodiments can be combined to achieve beneficial effects. Other variations of the disclosed embodiments after studying the accompanying drawings may be implemented, the specification and claims. In the claims, the term “comprising” does not exclude other means or steps; an article is intended to include one or more articles when it is not modified by a quantifier, and may be used interchangeably with “one or more articles”; the terms “first”, “second” are used to denote a name and not to denote any particular order. Any reference numeral in the claims should not be construed as limiting the scope of protection. The functions of several parts recited in the claims can be implemented by a single hardware or software module. The presence of certain technical features in different dependent claims does not indicate that these technical features cannot be combined to achieve beneficial effects.

What is claimed is:

1. A display module, comprising:
a base plate;
a light-emitting layer, arranged at one side of the base plate, and comprising a plurality of light-emitting units;
a light-filtering layer, arranged at a side of the light-emitting layer away from the base plate, and comprising a light-filtering portion, a light-shielding portion, and an optical adjustment portion; an orthographic projection of the light-filtering portion on the base plate at least partially overlaps an orthographic projection of the light-emitting unit on the base plate, at least one optical adjustment portion is arranged between adjacent light-filtering portions, the optical adjustment portion at least partially contacts with the light-filtering portion, and a refractive index of the optical adjustment portion is less than a refractive index of the light-filtering portion; an orthographic projection of the light-shielding portion on the base plate is located within an orthographic projection of the optical adjustment portion on the base plate.

2. The display module according to claim 1, wherein the orthographic projection of the optical adjustment portion on the base plate is spaced apart from the orthographic projection of the light-emitting unit on the base plate.

3. The display module according to claim 2, wherein in a direction parallel to the base plate, a difference between a distance from the light-filtering portion to an edge of the optical adjustment portion and a distance from the light-filtering portion to an edge of the light-shielding portion is L, and L satisfies: 3 μm≤L≤6 μm.

4. The display module according to claim 2, wherein the light-emitting units comprise a first light-emitting unit, a second light-emitting unit, and a third light-emitting unit that are different from one another in color, the light-filtering layer comprises a first light-filtering portion, a second light-filtering portion, and a third light-filtering portion, an orthographic projection of the first light-filtering portion on the base plate at least partially overlaps that of the first light-emitting unit, an orthographic projection of the second light-filtering portion on the base plate at least partially overlaps that of the second light-emitting unit, and an orthographic projection of the third light-filtering portion on the base plate at least partially overlaps that of the third light-emitting unit; and
in a direction parallel to the base plate, a difference between a distance from the first light-filtering portion to an edge of the optical adjustment portion and a distance from the first light-filtering portion to an edge of the light-shielding portion is L1, a difference between a distance from the second light-filtering portion to the edge of the optical adjustment portion and a distance from the second light-filtering portion to the edge of the light-shielding portion is L2, and a difference between a distance from the third light-filtering portion to the edge of the optical adjustment portion and a distance from the third light-filtering portion to the edge of the light-shielding portion is L3, and L1, L2 and L3 satisfy:
L1>L2, and L1>L3; wherein light-emitting efficiency of the first light-emitting unit is less than light-emitting efficiency of the second light-emitting unit, and less than light-emitting efficiency of the third light-emitting unit.

5. The display module according to claim 4, wherein L1, L2 and L3 satisfy: L1>L2>L3; wherein white light brightness ratio of the third light-emitting unit is greater than white light brightness ratio of the first light-emitting unit, and greater than white light brightness ratio of the second light-emitting unit.

6. The display module according to claim 5, wherein the first light-emitting unit is a blue light-emitting unit, and the third light-emitting unit is a green light-emitting unit.

7. The display module according to claim 1, wherein the orthographic projection of the optical adjustment portion on the base plate partially overlaps the orthographic projection of the light-filtering portion on the base plate.

8. The display module according to claim 7, wherein an angle between a sidewall surface of the optical adjustment portion facing the light-filtering portion and a plane in a direction parallel to the base plate is α, and α satisfies: 60°≤α≤90°.

9. The display module according to claim 8, wherein α satisfies: 70≤α≤80°.

10. The display module according to claim 7, wherein
the light-emitting units comprise a first light-emitting unit, a second light-emitting unit, and a third light-emitting unit that are different from one another in color,
the light-filtering layer comprises a first light-filtering portion, a second light-filtering portion, and a third light-filtering portion,
an orthographic projection of the first light-filtering portion on the base plate at least partially overlaps that of the first light-emitting unit, an orthographic projection of the second light-filtering portion on the base plate at least partially overlaps that of the second light-emitting unit, and an orthographic projection of the third light-filtering portion on the base plate at least partially overlaps that of the third light-emitting unit; and
an angle between a sidewall surface of the optical adjustment portion facing the first light-filtering portion and a plane in a direction parallel to the base plate is α1, an angle between a sidewall surface of the optical adjustment portion facing the second light-filtering portion and the plane in the direction parallel to the base plate is α2, an angle between a sidewall surface of the optical adjustment portion facing the third light-filtering portion and the plane in the direction parallel to the base plate is α3, and α1, α2, and α3 satisfy: |α1-β|<|α2-β|, and |α1-β|<|α3-β|, wherein β is a critical angle at which total reflection of light occurs at an interface where the optical adjustment portion contacts the light-filtering portion; and light-emitting efficiency of the first light-emitting unit is less than light-emitting efficiency of the second light-emitting unit, and less than light-emitting efficiency of the third light-emitting unit.

11. The display module according to claim 10, wherein α1, α2, and α3 satisfy: |α1-α3|>═α1-α2|, wherein white light brightness ratio of the third light-emitting unit is greater than white light brightness ratio of the first light-emitting unit, and greater than white light brightness ratio of the second light-emitting unit.

12. The display module according to claim 11, wherein the first light-emitting unit is a blue light-emitting unit, and the third light-emitting unit is a green light-emitting unit.

13. The display module according to claim 1, wherein the light-emitting layer further comprises a pixel definition layer, the pixel definition layer has a pixel opening, the light-emitting unit is located in the pixel opening, and the orthographic projection of the optical adjustment portion on the base plate is located within an orthographic projection of the pixel definition layer on the base plate; and in a direction parallel to the base plate, a distance between the optical adjustment portion and a sidewall surface of the pixel opening is D, and D satisfies: 0 μm≤D≤5 μm.

14. The display module according to claim 1, wherein the optical adjustment portion comprises an organic material, and the optical adjustment portion comprises at least one of polyimide or polymethyl methacrylate.

15. The display module according to claim 14, wherein a thickness of the optical adjustment portion is H, and H satisfies: 1.5 μm≤H≤5 μm.

16. The display module according to claim 1, wherein the refractive index of the optical adjustment portion is n1, and n1 satisfies: n1≤1.55; and the refractive index of the light-filtering portion is n2, and n2 satisfies: n2×1.6.

17. The display module according to claim 1, wherein the display module further comprises a protection layer arranged at a side of the light-filtering layer away from the base plate, and a refractive index of the protection layer is less than the refractive index of the light-filtering portion.

18. The display module according to claim 1, wherein the optical adjustment portion is arranged at a side of the light-shielding portion away from the base plate; the optical adjustment portion wraps at least a sidewall surface of the light-shielding portion; and the display module further comprises a touch control layer arranged between the light-emitting layer and the light-filtering layer, the touch control layer comprises an insulation layer, and a material of the optical adjustment portion is the same as a material of the insulation layer.

19. The display module according to claim 1, wherein the optical adjustment portion is arranged between the light-emitting layer and the light-shielding portion; and the display module further comprises a touch control layer arranged between the light-emitting layer and the light-filtering layer, and the optical adjustment portion is reused as an insulation layer in the touch control layer.

20. A display apparatus, comprising the display module according to claim 1.
